(19) United States
(12) Patent Application Publication
(10) Pub. No.: US 2007/0209200 A1
(43) Pub. Date: Sep. 13, 2007

(54) Circuit Board, Method Of Manufacturing Circuit Board, And Display Device Having Circuit Board

(75) Inventors: Tadahiro Ohmi, Sendai-shi (JP); Keiichi Nii, Sendai-shi (JP); Teruhiko Suzuki, Tokyo (JP); Takeyoshi Kato, Tokyo (JP)

Correspondence Address: BIRCH STEWART KOLASCH & BIRCH, PO BOX 747, FALLS CHURCH, VA, 22040-0747, US

(73) Assignees: Tadahiro OHMI, Miyagi (JP); Zeon Corporation, Tokyo (JP)

(21) Appl. No.: 10/594,596

(22) PCT Filed: Mar. 30, 2005
(86) PCT No.: PCT/JP05/06150

§ 371 Date: May 25, 2007

(30) Foreign Application Priority Data
Mar. 31, 2004 (JP) 2004-108559

(51) Int. Cl. H05K 3/10

(52) U.S. Cl. 29/846; 349/5

(57) ABSTRACT

A circuit board manufacturing method includes formation of a thermosetting photosensitive resin film on an insulating board by a spin coat method and the like, exposure of the photosensitive resin film to radiation rays such as ultraviolet rays, development with a developer or by etching, heat-hardening of the photosensitive resin film, oxygen plasma treatment or ultraviolet treatment if required, adjustment of a water quantity in the photosensitive resin film by drying the resin film, exposure in a fluorine gas atmosphere, anneal treatment, and then immersion of the resin film in a fluorinated acid chemical.

### TECHNICAL FIELD

This invention relates to a circuit board adapted for electrical/electronic use, a method of manufacturing the circuit board, and a display device having the circuit board.

### BACKGROUND ART

A board for electronic devices and apparatuses is formed by disposing, on an insulating substrate such as a glass or resin substrate or on a substrate of which at least the surface is made of an insulator, many thin film transistors and a single electrical wiring layer or multiple electrical wiring layers adapted for connection between those transistors or between the transistors and a power supply or input/output terminals.

As one of typical embodiments of the board for electronic devices and apparatuses, there is a display device such as an active matrix liquid crystal display device or organic EL display device. The entire board including scan lines, signal lines, and so on is also called an active matrix board, which is constituted by forming, on the surface of a substrate, circuit patterns in layers through processes such as film formation and photolithography in a decompressed atmosphere. In terms of cost reduction of the display device, reduction of the film formation process and the photolithography process in the decompressed atmosphere has been discussed.

Particularly, in the process of forming the wiring by sputtering, a wiring material deposited over the entire surface is processed by a photolithography method to thereby form wiring portions. Therefore, most of the wiring material is removed by etching. Further, a target of the wiring material, which is large as compared with the area of the substrate, is used for ensuring uniformity of the film thickness. Accordingly, the utilization efficiency of the wiring material is extremely low, which is a main cause for increasing the manufacturing cost of the electronic device board.

In order to solve such a problem, development has been made of a technique that forms wiring only at necessary portions by a printing method to thereby enhance the utilization efficiency of a wiring material. For example, Japanese Unexamined Patent Application Publication (JP-A) No. 2002-026014 discloses a method of forming wiring only at predetermined portions by the use of an inkjet method. By the use of such a printing method, the decompression process can be eliminated to reduce the manufacturing cost of the display device. Normally, in the case of forming wiring by the use of the inkjet method, use is made of a method in which there is provided a convex partition member (also called a “bank” or a “convex portion”) that partitions a portion where the wiring is to be formed, and a liquid conductive material to be the wiring is filled in the region surrounded by the partition member.

In this event, when the partition member has liquid affinity or wettability with respect to the liquid conductive material, the liquid conductive material is pulled by the partition member so as to be wetted over the outside of the partition member and therefore it is not possible to obtain a required wiring width finally. On the other hand, it is necessary that the bottom surface of the region surrounded by the partition member have high affinity or wettability with respect to the conductive material so that the liquid conductive material is uniformly wetted over the bottom surface. If the wettability to the conductive material is weak, the conductive material is not wetted over the region surrounded by the partition member. This causes disconnection in the case of wiring.

In view of such a problem, for example, Japanese Unexamined Patent Application Publication (JP-A) No. H9-203803, Japanese Unexamined Patent Application Publication (JP-A) No. H9-230129, and Japanese Unexamined Patent Application Publication (JP-A) No. 2000-353594 each propose a surface treatment technique that makes an upper portion of a partition member liquid-repellent and other portions liquid-affinitive. This surface treatment technique is a technique such that a plasma of gas containing a fluorine compound is irradiated at reduced pressure or atmospheric pressure for making the upper portion of the partition member liquid-repellent. Further, description is made of a method of treating with a hydrophilic radical-containing surfactant for making liquid-affinitive the bottom surface of a region surrounded by the partition member, a method of providing affinity by ultraviolet irradiation, and so on.

However, when forming a wire having a fine width of 10 μm or less by the inkjet method, there is a problem that the liquid material overflows or is excessively wetted over because of an insufficient difference in liquid affinity/repellency between the upper portion of the partition member and the bottom surface of the region surrounded by the partition member. For example, when forming a liquid-repellent portion by plasma irradiation, if a partition member is made of an organic material, etching reaction of a fluorine compound proceeds simultaneously with formation of the fluorine compound and, therefore, only certain liquid repellency is obtained. Further, since a plasma apparatus itself is quite complicated, there is a problem that the production line becomes quite complicated in the case of the actual manufacture of electronic device circuit boards.

Further, when forming a liquid-affinitive portion, fluorine compound plasma treatment is generally carried out after the treatment using the hydrophilic radical-containing surfactant or the ultraviolet irradiation as described above. However, there is a problem that since the fluorine compound is formed also at the portion which should primarily be made liquid-affinitive, the effect is lowered. Further, since the plasma treatment is anisotropic treatment, only the upper surface of the partition member is fluorinated. As a result, there is a problem that the value of liquid repellency at the side wall portion is low relative to the value of liquid repellency at the bottom surface of a pattern and therefore, the receptability of the liquid conductive material for fine wiring formation is poor.

On the other hand, a technique that forms a fluorine compound by exposing an organic material for use as a partition member to a fluorine gas atmosphere has been known. For example, Japanese Unexamined Patent Application Publication (JP-A) No. H6-69190 proposes a technique of obtaining a fluororesin film by exposing a photosensitive resin to a fluorine gas atmosphere. By exposure to the fluorine gas atmosphere, C—H bonds are replaced by C—F bonds so that fluorine atoms are added to carbon unsaturated bonds, and therefore, the fluororesin can be obtained. However, if the method of Japanese Unexamined Patent Application Publication (JP-A) No. H6-69190 is carried out as it is, a hydrofluoric acid is often produced and an organic material or a silicon-based substrate material is degraded due to the produced hydrofluoric acid.

Patent Document 1:

Japanese Unexamined Patent Application Publication (JP-A) No. H9-203803

Patent Document 2:

Japanese Unexamined Patent Application Publication (JP-A) No. H9-230129

Patent Document 3:

Japanese Unexamined Patent Application Publication (JP-A) No. 2000-353594

Patent Document 4:

Japanese Unexamined Patent Application Publication (JP-A) No. H6-69190

### DISCLOSURE OF THE INVENTION

### Problem to be Solved by the Invention

Therefore, an object of this invention is to provide a method of manufacturing a circuit board that can give sufficient contrast to wettability of a liquid conductive material between a partition member and an insulating substrate without degrading the partition member, thereby realizing fine wiring formation by an inkjet method.

Another object of this invention is to provide a display device using the foregoing circuit board.

According to the assiduous study for accomplishing the foregoing objects, the present inventors, at first, have found that it is effective for improving liquid repellency of a formed partition member to carry out processes of forming a thermosetting photosensitive resin film on an electronic device circuit substrate, exposing/developing, heat-hardening, and drying the resin film, and exposing the resin film to a fluorine gas atmosphere. Further, they have found that plasma treatment or immersion treatment using a hydrofluoric acid-based chemical solution, which is carried out before or after the foregoing processes, is effective for making the substrate surface liquid-affinitive. Moreover, they have found that high-contrast liquid repellency to a liquid material is obtained by combining those methods to enable finer formation of wiring. As a result, they have completed this invention.

### MEANS FOR SOLVING THE OBJECTS

This invention has the following aspects.

(First Aspect)

A method for manufacturing a circuit board, comprising the steps of:

forming a resin film on an insulating substrate, thereafter

exposing and developing the resin film,

heat-hardening the resin film, and

exposing the resin film to a fluorine gas atmosphere after drying the resin film.

(Second Aspect)

A method for manufacturing a circuit board, comprising the steps of:

forming a resin film on an insulating substrate,

exposing and developing the resin film,

heat-hardening the resin film,

drying the resin film, and thereafter

exposing the resin film to a fluorine gas atmosphere.

(Third Aspect)

A method for manufacturing a circuit board, comprising the steps of:

forming a resin film on an insulating substrate,

exposing and developing the resin film,

drying the resin film,

exposing the resin film to a fluorine gas atmosphere, and thereafter

heat-hardening the resin film.

(Fourth Aspect)

A method for manufacturing a circuit board, comprising the steps of:

forming a resin film on an insulating substrate,

heat-hardening the resin film,

drying the resin film,

exposing the resin film to a fluorine gas atmosphere, and exposing and developing the resin film.

Preferred aspects of the circuit board manufacturing method according to this invention are as follows.

(Fifth Aspect)

The water content in the resin film is 1 wt % or less after the drying step.

(Sixth Aspect)

The water concentration in the fluorine gas atmosphere is 100 wt ppm or less.

(Seventh Aspect)

The step of heat-hardening the resin film is carried out in an inert gas atmosphere.

(Eighth Aspect)

The resin film is subjected to ultraviolet irradiation at atmospheric pressure before the step of exposing the resin film to the fluorine gas atmosphere.

(Ninth Aspect)

The method further comprises a step of applying oxygen plasma treatment to the resin film at normal pressure or reduced pressure before the step of exposing the resin film to the fluorine gas atmosphere.

(Tenth Aspect)

The method further comprises a step of contacting the insulating substrate with a hydrofluoric acid-based chemical solution after the step of exposing the resin film to the fluorine gas atmosphere.

(Eleventh Aspect)

The hydrofluoric acid-based chemical solution is a hydrofluoric acid aqueous solution having a hydrofluoric acid concentration of 0.1 wt % to 50 wt %.

(Twelfth Aspect)

The hydrofluoric acid-based chemical solution contains one or more kinds of chemicals selected from the group consisting of inorganic acids, fluoride salts, and surfactants.

(Thirteenth Aspect)

The method further comprises a step of filling a conductive material in a concave portion formed by development of the resin film to form electrical wiring.

(Fourteenth Aspect)

Filling of the conductive material is carried out by any one of a plating method and a printing method.

(Fifteenth Aspect)

The printing method is inkjet printing or screen printing.

(Sixteenth Aspect)

The resin film and the electrical wiring form substantially the same plane.

(Seventeenth Aspect)

The insulating substrate is a glass substrate or a silicon wafer.

(Eighteenth Aspect)

The conductive material comprises an organic substance.

(Nineteenth Aspect)

The resin film is made from a photosensitive resin composition comprising an alkali-soluble alicyclic olefin resin and a radiation-sensitive component.

(Twentieth Aspect)

The resin film comprises one or more kinds of resins selected from the group consisting of an acrylic resin, a silicone resin, a fluorine resin, a polyimide resin, a polyolefin resin, an alicyclic olefin resin, and an epoxy resin.

(Twenty-First Aspect)

A circuit board obtainable by the aforementioned method.

(Twenty-Second Aspect)

A display device comprises the aforementioned circuit board.

(Twenty-Third Aspect)

The display device is a liquid crystal display device, an organic EL display device, or a plasma address display device.

### BRIEF DESCRIPTION OF THE DRAWINGS

FIG. 1 is a process diagram showing one embodiment of a circuit board manufacturing method of this invention.

FIG. 2 is a process diagram (continued) showing the embodiment of the circuit board manufacturing method of this invention.

FIG. 3 is a conceptual diagram of a burning apparatus for use in Examples of this invention.

FIG. 4 is a conceptual diagram of a fluorine gas atmosphere processing furnace for use in Examples of this invention.

FIG. 5 is a diagram showing the results of FT-IR analysis of a sample after annealing obtained in Example of this invention.

FIG. 6 is a sectional view showing the structure of an active matrix liquid crystal display of Example of this invention.

FIG. 7 is a top view showing the layout of the active matrix liquid crystal display of Example of this invention.

FIG. 8 is a diagram showing processes (a) to (d) of Example 10 of this invention.

FIG. 9 is a diagram showing processes (e) to (h) of Example 10 of this invention.

FIG. 10 is a diagram showing a process (i) of Example 10 of this invention.

### BEST MODE FOR CARRYING OUT THE INVENTION

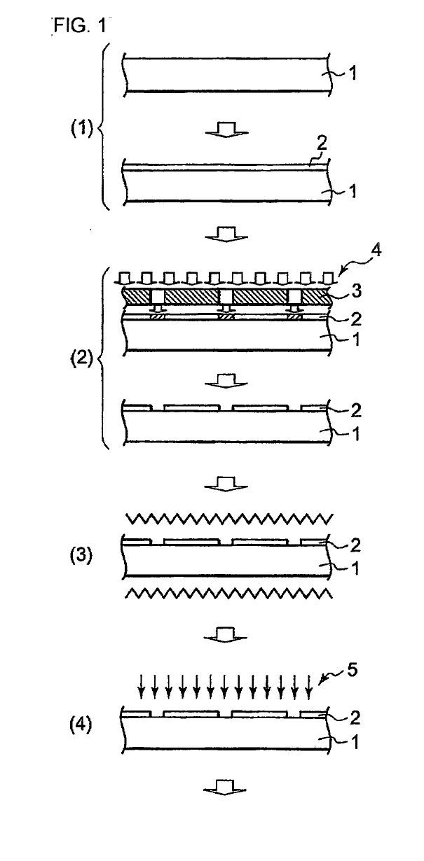

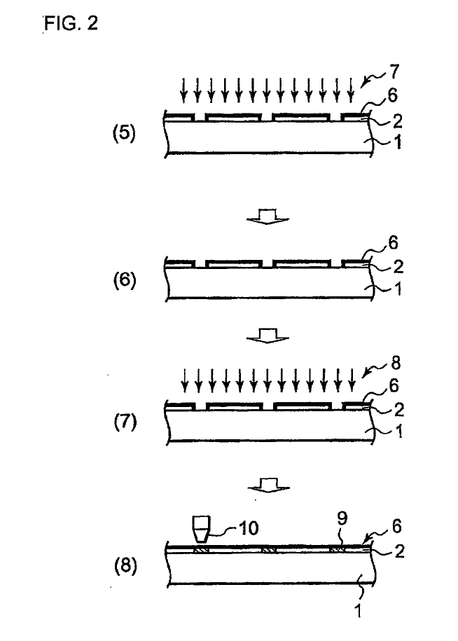

A circuit board manufacturing method of this invention will be described with reference to the drawings. FIGS. 1 and 2 show processes of one embodiment of the circuit board manufacturing method of this invention.

(1) Process of Forming a Resin Film on an Insulating Substrate

In this process, a thermosetting photosensitive resin film is formed on an insulating substrate.

An insulating substrate 1 is a substrate normally used in an electronic device circuit board and a glass substrate or a silicon wafer is preferably used.

A resin film 2 is normally made of a thermosetting photosensitive resin composition containing an alkali-soluble polymer component and a radiation-sensitive component. As the polymer component forming the thermosetting photosensitive resin composition, it contains at least one kind of resin selected from the group consisting of an acrylic-based resin, a silicone-based resin, a fluorine-based resin, a polyimide-based resin, a polyolefin-based resin, an alicyclic olefin-based resin, and an epoxy-based resin.

Among them, the acrylic-based resin, the silicone-based resin, and the alicydic olefin-based resin are preferable, and the acrylic-based resin and the alicydic olefin-based resin are particularly preferable. When using the alicyclic olefin-based resin, a crosslinking agent described in Japanese Unexamined Patent Application Publication (JP-A) No. 2004-212450 may also be used to provide the thermosetting property.

More specifically, there are cited a radiation-sensitive resin composition described in Japanese Unexamined Patent Application Publication (JP-A) No. 2004-47338 (US20030193624A1), a radiation-sensitive composition described in Japanese Unexamined Patent Application Publication (JP-A) No. 2003-288991 (US20030215737A1), a radiation-sensitive resin composition described in Japanese Unexamined Patent Application Publication (JP-A) No. 2003-302642, a radiation-sensitive resin composition described in Japanese Unexamined Patent Application Publication (JP-A) No. H10-26829, a radiation-sensitive resin composition described in Japanese Unexamined Patent Application Publication (JP-A) No. H9-230596, a radiation-sensitive resin composition described in Japanese Unexamined Patent Application Publication (JP-A) No. H9-146276, a radiation-sensitive resin composition described in Japanese Unexamined Patent Application Publication (JP-A) No. H8-262709, a radiation-sensitive resin composition described in Japanese Unexamined Patent Application Publication (JP-A) No. H10-10734, a radiation-sensitive resin composition described in Japanese Unexamined Patent Application Publication (JP-A) No. H8-240911, a radiation-sensitive resin composition described in Japanese Unexamined Patent Application Publication (JP-A) No. H8-183819, a radiation-sensitive resin composition described in Japanese Unexamined Patent Application Publication (JP-A) No. 2004-212450, and so on. Among them, use is preferably made of a thermosetting photosensitive resin composition containing an alkali-soluble alicyclic olefin-based resin and a radiation-sensitive component.

The resin film may contain an inorganic substance. A forming method of the resin film 2 is not particularly limited. The resin film 2 may be formed by spin coating, slit coating, or screen printing of the thermosetting photosensitive resin composition. The spin coating or slit coating is preferable for forming a thin film of 5 μm or less. Particularly, the spin coating is most preferable for forming a thin film with excellent thickness uniformity in the substrate.

(2) Exposure Process and Development (or Etching) Process

A mask 3 having a predetermined pattern is placed on the resin film 2 formed by coating or the like of the thermosetting photosensitive resin composition and radiation 4 such as ultraviolet radiation (g-line, h-line, i-line, or the like) is irradiated. The wavelength, intensity, and so on of the radiation 4 are properly selected depending on fineness of the pattern. For example, the ultraviolet radiation having a wavelength of 365 nm and a light intensity of 10 mW/cm² is irradiated at an energy of 100 mJ/cm² in the air.

In order to enhance the resolution after the exposure and development, prebaking can be carried out, for example, on a hot plate at 120° C. for about 1 minute. Depending on the kind of radiation-sensitive component, the resin film 2 may be one (positive-type) in which a portion irradiated with the radiation can be easily removed by a developer or another one (negative-type) in which a portion irradiated with the radiation can hardly be removed by a developer. Process (2) in FIG. 1 shows a development process of the positive-type resin film. After the exposure, the pattern is developed by the use of a developer. As the developer, a conventionally known one can be used and, for example, use is made of an organic alkali such as amine or organic ammonium salt, or an inorganic alkali such as sodium hydroxide or potassium hydroxide. Rinsing can also be carried out after the development with the developer. Instead of the development with the developer, the pattern may be formed by etching.

(3) Heat-Hardening Process

The resin film 2 is heat-hardened to thereby fix the pattern. A heat-hardening method is not particularly limited. For example, it may be heated on a hot plate at 240° C. for 30 minutes so as to be hardened and is preferably heated in an inert gas atmosphere. The temperature during the heat hardening is preferably 150° C. or more and particularly preferably 200° C. or more.

(4) Process of Oxygen Plasma Treatment or Ultraviolet Irradiation Treatment

Before carrying out later-described treatment with a fluorine gas, it is preferable to carry out oxygen plasma treatment or ultraviolet irradiation treatment 5.

The ultraviolet irradiation is normally carried out at atmospheric pressure. The oxygen plasma treatment is carried out at normal pressure or reduced pressure. Carrying out the oxygen plasma treatment or the ultraviolet irradiation treatment is preferable for increasing the difference in liquid repellency between the surface of the resin film 2 and the surface of the insulating substrate. Although the pattern of the resin film 2 can be formed by the exposure and development or the etching, resin residue remains on the surface of the insulating substrate in that event. This treatment is effective for removing it. If exposure to a fluorine gas atmosphere is carried out while the resin residue remains at a portion where the insulating substrate is exposed, a fluorine compound is formed on the surface of the residue to thereby make it difficult to obtain the difference in liquid repellency between the surface of the resin film 2 and the opening portion.

(5) Resin Film Drying Process and Fluorine Gas Exposure Process (Fluorination Process)

It is necessary to dry the resin film 2 before the exposure to the fluorine gas atmosphere. By drying the resin film 2, the water content in the resin film 2 is preferably set to 1 wt % or less, more preferably 0.1 wt % or less, and further preferably 0.05 wt % or less. If the water content is high, a fluorine gas 7 and the water often react together to produce hydrogen fluoride, so as to prevent surface treatment of the resin and cause inconveniences such as change in quality of the resin film 2 and stripping thereof from the substrate. A drying method is not particularly limited, but the resin film is preferably heated to 50° C. or more and more preferably 100° C. or more in an inert gas atmosphere.

After adjusting the water in the resin film 2 by the drying, the resin film 2 is exposed to the atmosphere of the fluorine gas 7. The fluorine gas concentration in the fluorine gas atmosphere is not particularly limited, but is preferably 0.1 to 50 vol %, more preferably 0.3 to 30 vol %, and further preferably 0.5 to 20 vol %. If the fluorine gas concentration is too low, production of a fluorine compound 6 on the surface of the resin film 2 is delayed. On the other hand, if the concentration is too high, rapid reaction with the resin film 2 occurs, which may be unpreferable. It is preferable that the fluorine gas 7 be diluted with a noble gas or an inert gas such as nitrogen so as to be used. There is no particular limitation to a method of exposing the insulating substrate 1 formed with the resin film 2 to the fluorine gas atmosphere. For example, use is made of a method of circulating the fluorine gas 7 at normal pressure in a container or a method of hermetically sealing it under increased pressure.

The water content in the fluorine gas atmosphere for treating the insulating substrate 1 formed with the resin film 2 is also preferably smaller because it is effective for the surface treatment. The water content in the fluorine gas atmosphere is preferably 100 wt ppm or less, more preferably 50 wt ppm or less, and further preferably 10 wt ppm or less. If the water concentration exceeds the foregoing range, hydrogen fluoride is often produced to cause various inconveniences.

In the method of this invention, the order of carrying out the foregoing processes (2), (3), and (5) after carrying out the foregoing process (1) is not particularly limited, but it is preferable to carry out in order of the foregoing processes (2), (3), and (5).

(6) Heat-Annealing Process

It is very effective for improving the liquid repellency of the surface to carry out post-heating called annealing in an inert gas atmosphere after exposing the insulating substrate 1 formed with the resin film 2 to the fluorine gas atmosphere, which is thus preferable. The annealing achieves an effect of accelerating production of the fluorine compound 6 at unreacted portions and volatilizing an excessive fluorine portion. The kind of inert gas for use in the annealing is not particularly limited, but use is made of a noble gas such as helium, neon, argon, krypton, xenon, or radon, or nitrogen. The annealing temperature differs depending on a softening point of the resin used in the thermosetting photosensitive resin composition, but is preferably 50° C. to 350° C., more preferably 100 to 350° C., and particularly preferably 200 to 350° C. This is because if the annealing temperature is too high, an inconvenience that the produced fluorine compound 6 excessively volatilizes to thereby reduce the resin film 2 is caused to occur, while conversely, if it is too low, the annealing effect does not appear.

(7) Hydrofluoric Acid Treatment Process

For forming the difference in liquid repellency between the surface of the resin film 2 and the opening portion of the insulating substrate, it is preferable to further include a process of contacting the insulating substrate 1 with a hydrofluoric acid-based chemical solution 8 after the process of the exposure to the fluorine gas atmosphere. Herein, the hydrofluoric acid-based chemical solution represents a chemical solution containing hydrofluoric acid. Even by carrying out the foregoing residue removal process ((4) Process of Oxygen Plasma Treatment or Ultraviolet Irradiation Treatment as described above) to remove the resin residue at the portion where the insulating substrate is exposed (the opening portion of the insulating substrate 1), the opening portion of the insulating substrate 1 is also subjected to formation of the fluorine compound layer 6 by the exposure to the fluorine gas atmosphere. Therefore, it is preferable to carry out the process of removing such a layer. The hydrofluoric acid-based chemical solution 8 to be used is preferably one obtained by diluting hydrogen fluoride with ultrapure water. The concentration of diluted hydrogen fluoride is preferably 0.1 wt % to 50 wt % and more preferably 0.5 to 10 wt %. If the hydrogen fluoride concentration is too high, inconveniences such as degradation of the resin film 2 and stripping thereof from the insulating substrate 1 occurs, while conversely, if it is too low, no effect of removal of the fluorine compound layer 6 is obtained at the opening portion. There is no particular limitation to a method of contacting between the hydrogen fluoride diluted with the ultrapure water and the insulating substrate 1, treatment by an immersion method in a fluororesin container or treatment with a fluid using a chemical solution nozzle is exemplified.

When the hydrogen fluoride diluted with the ultrapure water is used as the hydrofluoric acid-based chemical solution, the resin film 2 is often subjected to the occurrence of inconvenience depending on the treatment condition as described above. Further, when the insulating substrate 1 is the silicon-based substrate, there arise problems that the surface roughness of the substrate increases, insoluble foreign matter is produced, and so on. Therefore, it is desirable that the hydrofluoric acid-based chemical solution 8 contain one or more kinds of chemicals selected from the group consisting of inorganic acids, fluoride salts, and surfactants. As these chemical kinds, use may be made of any of, preferably, inorganic acids such as hydrochloric acid, sulfuric acid, nitric acid, and hydrogen bromide, fluoride salts such as ammonium fluoride, tetramethylammonium fluoride, and tetraethylammonium fluoride, cationic surfactants (primary amine salt, secondary amine salt, tertiary amine salt, quaternary ammonium salt, alkylpyridinium salt, and so on), anionic surfactants (carboxylic acid, sulfonic acid, alkali metal salt of sulfonic acid, alkali metal salt of sulfuric acid monoester, and so on), and nonionic surfactants (polyoxyethylenealkylether, polyoxyethylenealkylphenolate, sucrose fatty acid ester, aliphatic alcohol, monoglyceride, and so on).

(8) Wiring Forming Process

After the foregoing process, a conductive material is filled into a region partitioned by the resin film 2 (hereinafter may also be referred to as the partition member) (i.e. a concave portion) to thereby form electrical wiring 9. The process of filling the conductive material (the conductive material during the filling may also be referred to as the wiring precursor) between the partition members is preferably carried out by a plating method or a printing method and, in the case of the printing method, an inkjet printing method or a screen printing method is preferable. Particularly, in the inkjet method, since the liquid affinity/repellency to the liquid wiring precursor differs between the upper surface of the partition member and the exposed surface at the opening portion of the insulating substrate 1, the wiring precursor can be selectively filled between the partition members.

The kind of wiring precursor is not particularly limited, but, as the kind of metal contained, it is preferable to contain one or more kinds of metals selected from the group consisting of gold, platinum, silver, copper, nickel, palladium, manganese, chromium, aluminum, and so on. Particularly, gold, silver, copper, nickel, or the like is preferable for formation of fine wiring because it is possible to use particles of 1 μm or less. The kind of solvent for the wiring precursor is not particularly limited, such as a water-based one, an organic solvent-based one, or a mixture thereof, but it is preferable that the difference in liquid affinity/repellency appears between the partition member and the surface of the insulating substrate. As described in Japanese Unexamined Patent Application Publication (JP-A) No. 2002-324966, the conductive material preferably contains an organic substance.

In this invention, an electronic device circuit board can be obtained by the foregoing circuit board manufacturing method. The structure of the electronic device circuit board is not particularly limited, but it is preferable that the partition member and the wiring form substantially the same plane. By making the partition member and the wiring surface form substantially the same plane, there is provided the circuit board that can reduce occurrence of disconnection, short circuit, or the like. “substantially the same plane” represents that the maximum height difference at a portion forming such a plane is 1.0 μm or less and preferably 0.5 μm or less. The circuit board obtained by the method of this invention is preferably used in a display device and particularly preferably used in a liquid crystal display device, an organic EL display device, or a plasma address display device.

### EXAMPLES

Hereinbelow, examples of this invention will be described. This invention is not limited to the following examples. Analysis values in the following examples and comparative examples are each derived by rounding to the nearest whole number and “parts” represents “weight parts”.

The analysis conditions in the following examples and comparative examples are as follows.

(Test 1) Thermal Desorption Spectroscopy (Hereinafter Abbreviated as “TDS Analysis”)
Apparatus: EMD-WA1000S/W manufactured by Denshi Kagaku Co., Ltd.

(Test 2) Fourier Transform Infrared Spectroscopy (Hereinafter Abbreviated as “FT-IR Analysis”)
Apparatus: Spectrum One manufactured by Perkin Elmer Corporation

(Test 3) Cavity Ring-Down Spectroscopy (Hereinafter Abbreviated as “CRDS Analysis”)
Apparatus: MTO-1000H2O manufactured by Tiger Optics, Inc.
   (Test 4) Contact Angle Measurement
Apparatus: CA-D manufactured by Kyowa Interface Science

Using tetradecane, the contact angle was defined as a value after a lapse of 30 seconds from contact of a droplet with a substrate.

(Test 5) Total Light Transmittance (Ultraviolet Spectroscopy)
Apparatus: UV-2550 manufactured by Shimadzu Corporation

The total light transmittance was defined as the average value of light transmittances at respective wavelengths between 400 nm and 800 nm.

(Test 6) Wiring Precursor Reception Possible Width

On a groove with a length of 50 mm formed by a partition member on a glass substrate, a wiring precursor was dropped and the number of portions where the wiring precursor exuded from the groove was evaluated. The wiring precursor reception possible width was defined as a width of the groove where no exudation portions occurred.

### Manufacturing Example 1

[Adjustment of Thermosetting Photosensitive Resin Composition (Positive-Type)]

62.5 parts of 8-hydroxycarbonyltetracyclo[4.4.0.1^{2,5}.1^{7,10}]

dodeca-3-ene, 37.5 parts of N-phenyl-(5-norbornene-2,3-dicarboximide), 1.3 parts of 1-hexene, 0.05 parts of 1,3-dimethylimidazolidine-2-iliden(tricyclohexylphosphine)benzylideneruthenium dichloride, and 400 parts of tetrahydrofuran were put in a pressure-proof reactor made of a nitrogen-substituted glass and reacted at 70° C. for 2 hours while being stirred, thereby obtaining a polymer solution A (solid concentration about 20%).

Part of the polymer solution A was moved into an autoclave with a stirrer and reacted, with hydrogen dissolved, at 150° C. and a pressure of 4 MPa for 5 hours, thereby obtaining a polymer solution B (solid concentration: about 20%) containing a hydrogenated polymer (hydrogenation ratio 100%).

A heat-proof container containing 100 parts of the polymer solution B with 1 part of activated carbon powder added was placed in the autoclave, and hydrogen was dissolved at 150° C. and a pressure of 4 MPa for 3 hours while stirring. Then, the solution was taken out and filtered through a fluororesin filter with a pore size of 0.2 μm to separate the activated carbon. Thus, a polymer solution was obtained. The filtration was smoothly carried out. The polymer solution was poured into an ethyl alcohol so as to be solidified and the produced crumb was dried to thereby obtain a polymer (1). The obtained polymer (1) had a Mw of 5,500 and a Mn of 3,200 in terms of polyisoprene. Further, an iodine value was 1.

100 parts of the polymer (1) were mixed with 20 parts of a condensation product of 1,1,3-tris(2,5-dimethyl-4-hydroxyphenyl)-3-phenylpropane (1 mole) and 1,2-naphthoquinonediazide-5-sulfonic acid chloride (1.9 moles) as a photosensitizer, 40 parts of a 1,2-epoxy-4-(2-oxiranyl)cyclohexane adduct of 2,2-bis(hydroxylmethyl)1-butanol (Tradename “EHPE3150” manufactured by Daicel Chemical Co., Ltd.) as a crosslinking agent, 4 parts of γ-glycidoxypropyltrimethoxysilane as an adhesion assistant, 5 parts of pentaerythritol tetrakis[3-(3,5-di-t-butyl-4-hydroxyphenyl)propionate] as an antioxidant, 0.2 parts of a silicone-based surfactant (Tradename “KP341” manufactured by Shinetsu Chemical Co., Ltd.) as a surfactant, and 550 parts of diethyleneglycolmethylethylether as a good solvent of the polymer (1) and dissolved, and then filtered through a polytetrafluoroethylene filter having a pore size of 0.20 μm (manufactured by Millipore Corporation), thereby obtaining a thermosetting photosensitive resin composition.

### Manufacturing Example 2

[Adjustment of Thermosetting Photosensitive Resin Composition (Negative-Type)]

300.0 parts of methyltrimethoxysilane, 47.5 parts of ion-exchanged water having an electrical conductivity of 8×10⁻⁵ S·cm⁻¹, and 0.1 parts of oxalic acid were put into a container with a stirrer and, then, methyltrimethoxysilane was hydrolyzed by heating and stirring under the conditions of 60° C. and 6 hours. Then, after adding 1,000 parts of propyleneglycolmonomethylether into the container, the ion-exchanged water and methanol secondarily produced by the hydrolysis were removed by the use of an evaporator, thereby obtaining a solution in which the solid content was adjusted to 25 wt %.

400 parts of the foregoing solution and 2.0 parts of phenyl, 4-(2′-hydroxy-1′-tetradecaoxy)phenyliodonium-p-toluenesulfonate serving as a radiation-sensitive acid forming agent were uniformly mixed and dissolved, and then filtered through a membrane filter having a pore size of 0.2 μm, thereby obtaining a thermosetting photosensitive resin composition.

### Example 1

[Confirmation of Fluoridation]

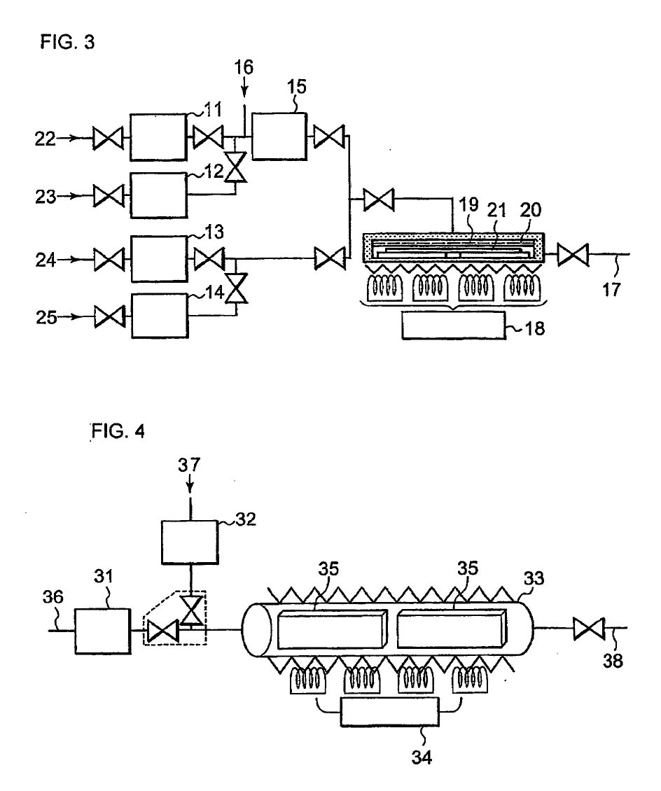

After cleaning a silicon wafer, dehydration heating was carried out in high-purity nitrogen. Thereafter, an adhesion layer was formed by steaming of hexamethylenedisilazane (HMDS). After forming the adhesion layer, the thermosetting photosensitive resin composition obtained in Manufacturing Example 1 was coated by a spin coating method to thereby form a resin film having a thickness of about 1 μm. The silicon wafer formed with the resin film was exposed at 200 mJ/cm² by the use of a mask aligner (PLA501 manufactured by CANON) and then developed so as to form a pattern, and thereafter, the entire substrate surface was exposed at 500 mJ/cm² (g-, h-, and i-lines mixed). Then, by heating in a high-purity nitrogen atmosphere at 280° C. for 60 minutes by the use of a burning apparatus of FIG. 3, the resin film was hardened.

In FIG. 3, nitrogen 22 and 24, oxygen 23, and hydrogen 25 are supplied to a burning furnace 20 through gas flow rate controllers 11 to 15. A shower plate 19 and substrates 21 are disposed in the burning furnace 20. Further, the burning furnace 20 is provided with a temperature adjuster 18. Herein, 16 and 17 denote exhaust lines.

After the hardening, the silicon wafer was placed in a fluorine gas atmosphere processing furnace of FIG. 4 and dried at 150° C. for 60 minutes while circulating a high-purity argon gas.

In FIG. 4, resin films 35 (illustration of silicon wafers being omitted) are disposed in a fluoridation processor 33. Further, the fluoridation processor 33 is provided with a temperature adjuster 34. With this structure, a fluorine gas 36 and an argon gas 37 are supplied to the fluoridation processor 33 through gas flow rate controllers 31 and 32 and then exhausted 38.

Part of the resin film after the drying was subjected to the TDS analysis to analyze the water content in the resin film and it was 0.02 wt %. After this drying, 10 vol % fluorine gas diluted with the high-purity argon gas and heated to 180° C. was introduced into the processing furnace at a flow rate of 200 cc/min to thereby carry out a fluoridation process for 5 minutes. The water content in the diluted fluorine gas was 10 wt ppm according to the CRDS analysis.

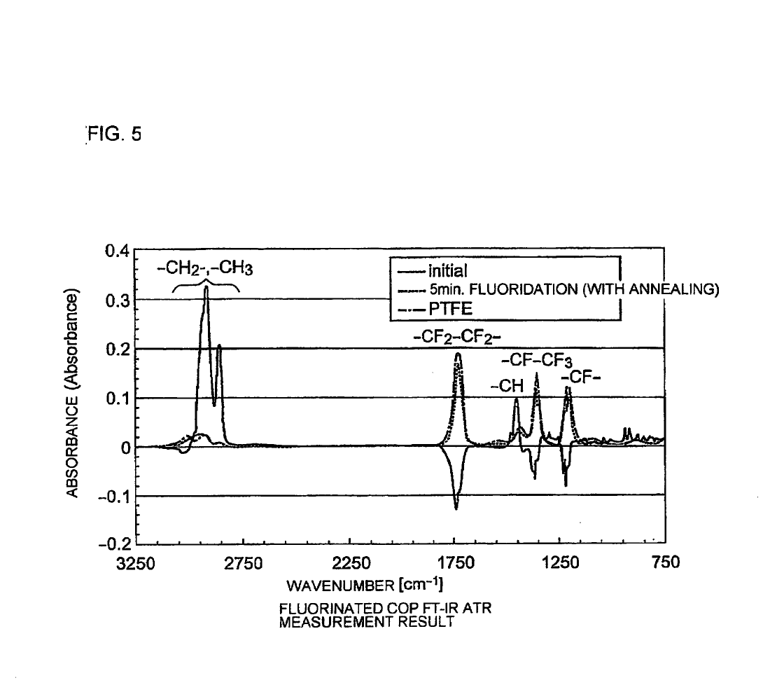

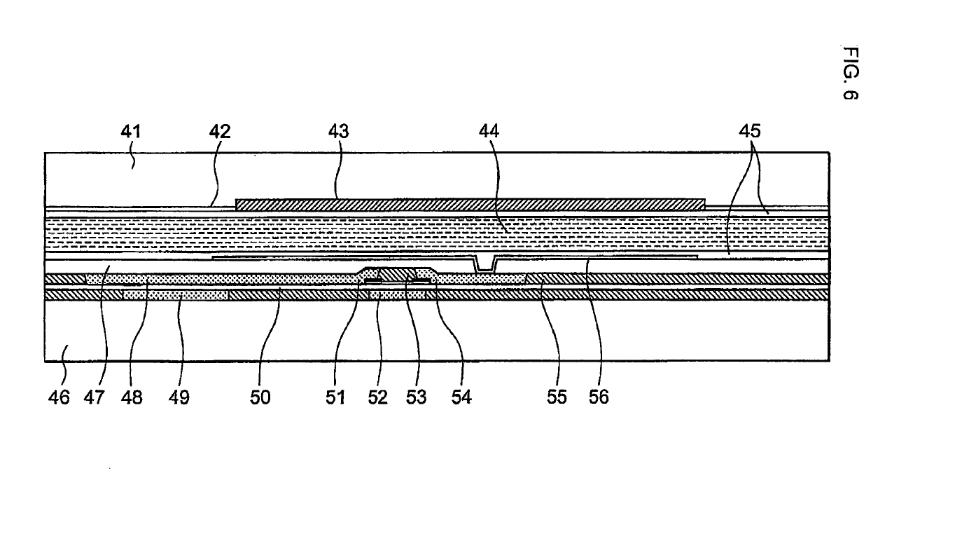

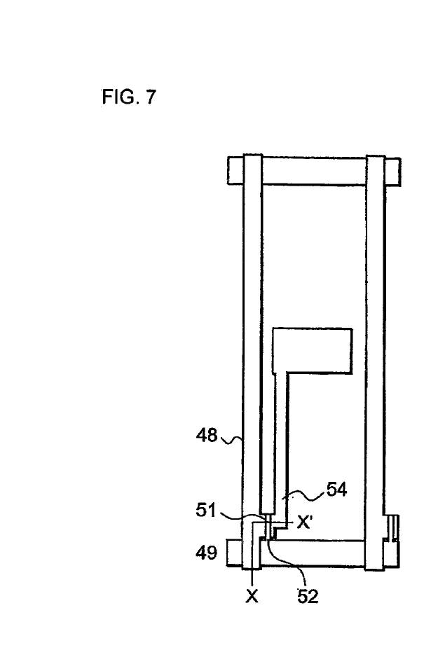

After the fluoridation process, annealing was carried out in the high-purity argon gas at 300° C. for 10 minutes. The results of FT-IR analysis of the sample after the annealing are shown in FIG. 5.

In the IR spectrum, absorption based on C—H bonds observed around 2930 cm⁻¹ disappeared by the foregoing fluoridation process and, instead, absorption based on C—F bonds was observed around 1250 cm⁻¹.

### Example 2

[Contact Angle, External Appearance, and Total Light Transmittance of Thermosetting Resin]

After cleaning a cleaned no-alkali glass substrate, dehydration heating was carried out in high-purity nitrogen. Thereafter, an adhesion layer was formed by a steaming treatment of hexamethylenedisilazane (HMDS). After forming the adhesion layer, the thermosetting photosensitive resin composition obtained in Manufacturing Example 1 was coated by a spin coating method to thereby form a resin film having a thickness of about 1 μm. The no-alkali glass substrate formed with the resin film was exposed at its half surface with 200 mJ/cm² by the use of the mask aligner and then developed. In this event, since the photosensitivity was positive, the exposed portion was dissolved so that the resin film at the half surface on the glass substrate was removed.

After the development, the entire substrate surface was exposed at 500 mJ/cm² by the use of the mask aligner (ultraviolet treatment process). Then, by heating in a high-purity nitrogen atmosphere at 280° C. for 60 minutes by the use of the burning apparatus of FIG. 3, the resin film was hardened. After the hardening, the no-alkali glass substrate was placed in the fluorine gas atmosphere processing furnace of FIG. 4 and dried at 150° C. for 60 minutes while circulating the high-purity argon gas. Part of the resin film after the drying was subjected to the TDS analysis to analyze the water content in the thermosetting resin film and it was 0.02 wt %. After this drying, 10 vol % fluorine gas diluted with the high-purity argon gas and heated to 180° C. was introduced into the processing furnace at a flow rate of 200 cc/min. In this manner, a fluoridation process was carried out for 1 minute. After the fluoridation process, annealing was carried out in the high-purity argon gas at 300° C. for 10 minutes. With respect to the no-alkali glass substrate after the annealing, the external appearance (presence/absence of stripping) of the sample, the contact angles of tetradecane (a solvent for use in a wiring precursor) relative to the resin surface and the glass surface, and the light transmittance were tested. The results are shown in Table 1.

### Example 3

An experiment was conducted in the same manner as in Example 2 except that the annealing temperature was set to 200° C. The results are shown in Table 1.

### Example 4

An experiment was conducted in the same manner as in Example 2 except that the annealing was not carried out. The results are shown in Table 1.

### Comparative Example 1

An experiment was conducted in the same manner as in Example 2 except that the drying, the fluoridation process, or the annealing was not carried out. The results are shown in Table 1.

### Comparative Example 2

An experiment was conducted in the same manner as in Example 2 except that the drying was not carried out. The results are shown in Table 1.

### Example 5

An experiment was conducted in the same manner as in Example 2 except that, after hardening a resin film, oxygen plasma treatment was carried out at a pressure of 20 mmHg for 10 seconds by the use of an RF plasma apparatus. The results are shown in Table 1.

### Example 6

An experiment was conducted in the same manner as in Example 5 except that, after the annealing, immersion was carried out in a 2.5 wt % hydrofluoric acid aqueous solution for 10 seconds and then rinsing was carried out with ultrapure water for 5 minutes. The results are shown in Table 1.

### Comparative Example 3

An experiment was conducted in the same manner as in Example 6 except that a fluoridation process was carried out not in the fluorine gas atmosphere but in a carbon tetrafluoride plasma at a pressure of 50 mmHg for 1 minute by the use of an RF plasma apparatus. The results are shown in Table 1.

### Example 7

An experiment was conducted in the same manner as in Example 6 except that, instead of the 2.5 wt % hydrofluoric acid aqueous solution treatment, treatment was carried out for 60 seconds using LAL1000 (a hydrofluoric acid-based chemical solution containing a surfactant, manufactured by Stella Chemifa). The results are shown in Table 1.

### Example 8

An experiment was conducted in the same manner as in Example 5 except that, as a thermosetting photosensitive resin composition, use was made of the one obtained in Manufacturing Example 2. The results are shown in Table 1.

TABLE 1

| | | | | | WATER | | |
|---|---|---|---|---|---|---|---|
| | KIND OF | | | | CONTENT IN | | |
| | THERMO- | | | | GAS DURING | | |
| | SETTING | | OXYGEN | | FLUORIDATION | ANNEALING | |
| | RESIN | HARDENING | PLASMA | DRYING | (WT ppm) | TEMPERATURE | TIME |
| Example 2 | ALICYCLIC | YES | NO | YES | 10 ppm | 300° C. | 10 min |
| | OLEFIN RESIN | | | | | | |
| Example 3 | ALICYCLIC | YES | NO | YES | 10 ppm | 200° C. | 10 min |
| | OLEFIN RESIN | | | | | | |
| Example 4 | ALICYCLIC | YES | NO | YES | 10 ppm | NO | |
| | OLEFIN RESIN | | | | | | |
| Example 5 | ALICYCLIC | YES | YES | YES | 10 ppm | 300° C. | 10 min |
| | OLEFIN RESIN | | | | | | |
| Example 6 | ALICYCLIC | YES | YES | YES | 10 ppm | 300° C. | 10 min |
| | OLEFIN RESIN | | | | | | |
| Example 7 | ALICYCLIC | YES | YES | YES | 10 ppm | 300° C. | 10 min |
| | OLEFIN RESIN | | | | | | |
| Example 8 | SILICONE | YES | YES | YES | 10 ppm | 300° C. | 10 ppm |
| | RESIN | | | | | | |
| Comparative | ALICYCLIC | YES | NO | NO | — | NO | |
| Example 1 | OLEFIN RESIN | | | | | | |
| Comparative | ALICYCLIC | YES | NO | NO | 10 ppm | 300° C. | 10 min |
| Example 2 | OLEFIN RESIN | | | | | | |
| Comparative | ALICYCLIC | YES | YES | YES | 10 ppm | 300° C. | 10 min |
| Example 3 | OLEFIN RESIN | | | | | | |

| | HYDROFLUORIC | | CONTACT | | | |
|---|---|---|---|---|---|---|
| | ACID | APPEARANCE | ANGLE | | LIGHT | TOTAL |
| | TREATMENT | STRIPPING | RESIN | GLASS | TRANSMITTANCE | EVALUATION |
| Example 2 | NO | NO | 62 | 13 | 99.9% | ◯ |
| Example 3 | NO | NO | 58 | 13 | 99.8% | ◯ |
| Example 4 | NO | NO | 55 | 13 | 99.8% | Δ |
| Example 5 | NO | NO | 62 | 8 | 99.9% | ⊚ |
| Example 6 | 2.5% HF | NO | 62 | <3 | 99.9% | ⊚ |
| Example 7 | LAL800 | NO | 60 | <3 | 99.7% | ⊚ |
| Example 8 | NO | NO | 60 | 8 | 99.1% | ◯ |
| Comparative | NO | NO | 12 | 10 | 99.7% | X |
| Example 1 | | | | | | |
| Comparative | NO | NO | 46 | 13 | 99.7% | X |
| Example 2 | | | | | | |
| Comparative | 2.5% HF | NO | 55 | <3 | 99.6% | Δ |
| Example 3 | | | | | | |

### Example 9

[Liquid Conductive Material Reception Possible Width]

After cleaning a cleaned no-alkali glass substrate, dehydration heating was carried out in high-purity nitrogen. Thereafter, an adhesion layer was formed by a steaming treatment of hexamethylenedisilazane (HMDS). After forming the adhesion layer, the thermosetting photosensitive resin composition obtained in Manufacturing Example 1 was coated by a spin coating method to thereby form a resin film having a thickness of about 1 μm. The no-alkali glass substrate formed with the resin film was subjected to exposure of linear patterns having widths of 10 to 50 μm and a length of 50 mm at 200 mJ/cm² by the use of the mask aligner and then developed. In this event, since the photosensitive resin composition had the positive photosensitivity, the exposed portions were dissolved so that groove patterns having widths of 10 to 50 μm were formed. After the development, the entire substrate surface was exposed at 500 mJ/cm² by the use of the mask aligner. Then, by heating in a high-purity nitrogen atmosphere at 280° C. for 60 minutes by the use of the burning apparatus of FIG. 3, the resin film was hardened.

Thereafter, oxygen plasma treatment was carried out at a pressure of 20 mmHg for 10 seconds by the use of an RF plasma apparatus. The no-alkali glass substrate was placed in the fluorine gas atmosphere processing furnace of FIG. 4 and dried at 150° C. for 60 minutes while circulating the high-purity argon gas. After the drying, 10 vol % fluorine gas diluted with the high-purity argon gas and heated to 180° C. was introduced into the processing furnace at a flow rate of 200 cc/min. Thus, a fluoridation process was carried out for 1 minute. After the fluoridation process, annealing was carried out in the high-purity argon gas at 300° C. for 10 minutes. After the annealing, immersion was carried out in a 2.5 wt % hydrofluoric acid aqueous solution for 10 seconds and then rinsing was carried out with ultrapure water for 5 minutes. Silver ink manufactured by Fujikura Kasei was dropped in the linear groove portions of the sample substrate by the use of a microsyringe. In this manner, the ink droplet reception possible width was evaluated. The results are shown in Table 2.

### Comparative Example 4

An experiment was conducted in the same manner as in Example 9 except that the oxygen plasma treatment, the drying, the fluoridation process, the annealing, or the hydrofluoric acid aqueous solution treatment was not carried out. The results are shown in Table 2.

### Comparative Example 5

An experiment was conducted in the same manner as in Example 9 except that a fluoridation process was carried out not in the fluorine gas atmosphere but in a carbon tetrafluoride plasma at a pressure of 50 mmHg for 1 minute by the use of an RF plasma apparatus. The results are shown in Table 2.

TABLE 2

| | | | | | | NUMBER OF | | | | | |
|---|---|---|---|---|---|---|---|---|---|---|---|
| | | | WATER | | | EXUDATION | | | | | |
| | | | CONTENT | ANNEALING | | PORTIONS | | | | | RECEPTION |
| | OXYGEN | | DURING | TEMPER- | | 50 | 40 | 30 | 20 | 10 | POSSIBLE |
| | PLASMA | DRYING | FLUORIDATION | ATURE | TIME | μm | μm | μm | μm | μm | WIDTH |
| EXAMPLE 9 | YES | YES | 10 ppm | 300° C. | 10 min | 0 | 0 | 0 | 0 | 0 | 10 μm |
| COMPARATIVE | — | — | — | — | — | ALL EXUDED | | | | | — |
| EXAMPLE 4 | | | | | | | | | | | |
| COMPARATIVE | YES | YES | 10 ppm | 300° C. | 10 min | 0 | 0 | 0 | 3 | 30 | 20 μm |
| EXAMPLE 5 | | | | | | | | | | | |

### Example 10

An active matrix display device (active matrix liquid crystal display) in Example 10 of this invention will be described with reference to the figures.

FIG. 6 is a sectional view showing the structure of the active matrix liquid crystal display of this Example 10.

The active matrix liquid crystal display comprises a scan line 49 formed on a glass substrate 46, a signal line 48, and a thin film transistor provided near a crossing portion between the scan line 49 and the signal line 48 and having a gate electrode 52 connected to the scan line 49 and a source electrode 51 or a drain electrode 54 connected to the signal line 48. A flattening layer 55 is formed so as to surround the signal line 48, the source electrode 51, and the drain electrode 54. Herein, the signal line 48, the source electrode 51, the drain electrode 54, and the flattening layer form substantially the same plane. On this plane, a pixel electrode 56 is disposed through an interlayer insulating film 47 to thereby form an active matrix board which holds liquid crystals 44 between itself and an opposing substrate 41. In this Example 10, hthe scan line 49 and the gate electrode wire 52 are in the form of buried wiring obtained by an inkjet method. Herein, 42 denotes a black matrix, 43 a color filter, 45 orientation layers, 53 a semiconductor layer, and 51 a gate insulating film.

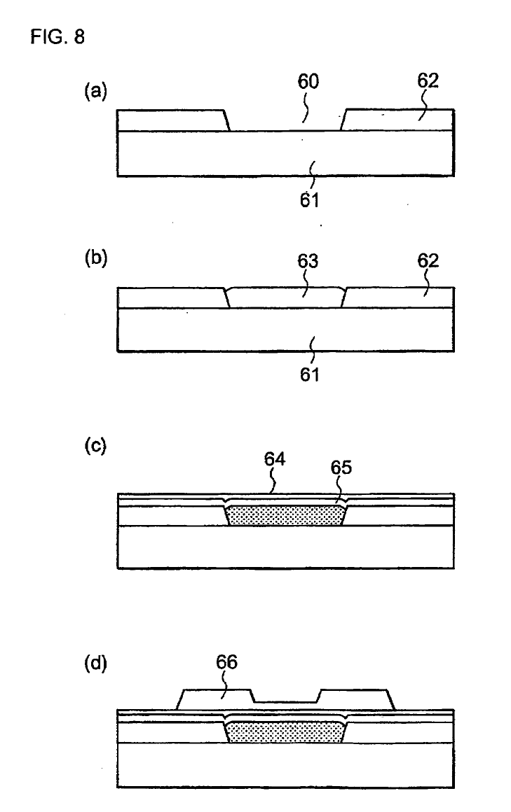

Next, referring to FIGS. 8 to 10, description will be made of a method of forming a gate electrode wiring portion.

At first, a thermosetting photosensitive resin film (alicyclic olefin resin-based transparent resin film) 62 having a thickness of 1 μm is formed on the surface of a glass substrate 61 by a spin coating method or the like. This resin film 62 has a function as a photoresist film. Then, the resin film 62 is selectively subjected to exposure by the use of a mask aligner and then is subjected to development and removal and heat-hardened. Thus, a wiring groove 60 was formed in the resin film 62 (see FIG. 8, (a)).

Particularly, when the wiring width 60 is very small, treatment is carried out to provide liquid repellency on the surface of the resin film 62 for the purpose of enhancing the printing accuracy. Specifically, drying is carried out after oxygen plasma treatment and then the glass substrate 61 is exposed in a fluorine gas atmosphere to fluorinate the surface thereof and, after annealing, immersed in a hydrofluoric acid aqueous solution.

Then, a wiring precursor (conductive material) is filled in the wiring groove 60 by a printing method such as an inkjet printing method or a plating method. The inkjet method is preferable as the wiring forming method in terms of efficient use of ink, but use may also be made of a screen printing method or the like. In this Example, silver paste ink as disclosed in Japanese Unexamined Patent Application Publication (JP-A) No. 2002-324966 was used as the wiring precursor to thereby form the wiring. After filling the wiring precursor, burning was carried out at a temperature of 250 degrees for 30 minutes. In this manner, a scan line 63 (corresponding to 49 in FIG. 6) and a gate electrode wire 63 were formed (corresponding to 52 in FIG. 6) (see FIG. 8, (b)).

Then, a silicon nitride film (SiNₓ film) was formed (illustration omitted) by the use of a SiH₄ gas, a H₂ gas, a N₂ gas, and an Ar gas according to a plasma CVD method using a microwave excited plasma. Although a SiNₓ film can also be formed by the use of a normal high-frequency excited plasma, the formation of the SiNₓ film can be achieved at a lower temperature by the use of the microwave excited plasma. The film formation temperature was set to 300° C. and the film thickness to 0.2 μm.

Then, an amorphous silicon layer 65 and an n+-type amorphous silicon layer 64 were formed by a plasma CVD method using a microwave excited plasma. The amorphous silicon layer 65 was formed by the use of a SiH₄ gas and the n+-type amorphous silicon layer 64 was formed by the use of a SiH₄ gas, a PH₃ gas, and an Ar gas, each at a temperature of 300° C. (see FIG. 8, (c)).

Then, a photoresist (photosensitive resin composition) was coated over the entire surface by a spin coating method and then dried on a hot plate at 100° C. for one minute to thereby remove a solvent. Then, using a g-line stepper, exposure was carried out in a dose amount of 36 mJ/cm² energy. For the exposure, a mask was formed so as to leave an element region and the exposure amount was adjusted by the use of a slit mask at a portion corresponding to a channel region inside the device region. As a result of carrying out puddle development for 70 seconds using a 2.38 wt % TMAH solution, a photoresist 66 having a shape as shown in FIG. 8, (d) was obtained.

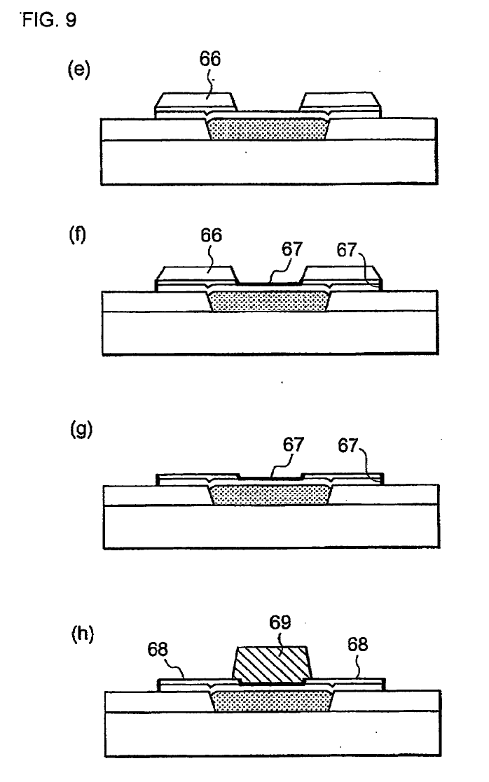

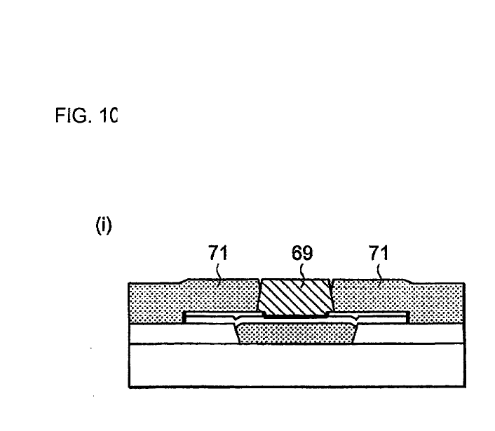

Then, using a plasma etching apparatus, the n+-type amorphous silicon layer 64 and the amorphous silicon layer 65 were etched. In this event, since the photoresist 66 is also etched to some extent to reduce its thickness, the resist at the channel region where the photoresist thickness is thin (the hollow portion of the photoresist 66) and also the n+-type amorphous silicon layer 64 are etched. The etching process is finished at a time instant when the n+-type amorphous silicon layer 64 and the amorphous silicon layer 65 at other than the device region portion (the portion covered with the photoresist 66) are removed by etching and when the n+-type amorphous silicon layer 64 in the channel region is removed by etching (see FIG. 9, (e)). The photoresist 66 still remains on the n+-type amorphous silicon layer 64 at a source electrode portion and a drain electrode portion.

Then, in this state, using an Ar gas, a N₂ gas, and a H₂ gas, microwave excited plasma treatment is carried out to directly form a nitride film 67 on the amorphous silicon surfaces at the channel region portion and on the sides of the device region portion (see FIG. 9, (f)).

It is also possible to directly form a nitride film 67 by the use of a general high-frequency plasma, but, by the use of the microwave excited plasma, it is possible to produce a plasma whose electron temperature is low. Therefore, the nitride film 67 can be directly formed without damaging the channel portion due to the plasma, which is thus preferable. It is also possible to form a nitride film by a CVD method. However, the nitride film is also formed over the source and drain electrode regions and therefore a removal process is required later. Therefore, it is more preferable to directly form the nitride film 67.

Then, the photoresist film 66 remaining on the source electrode region and the drain electrode region is subjected to oxygen plasma ashing and then removed by the use of a resist stripping solution or the like (see FIG. 9, (g)).

Subsequently, in order to form a resin film 69 that is required for forming a signal line, a source electrode wire, and a drain electrode wire by a printing method such as an inkjet printing method or a plating method, a thermosetting photosensitive resin film (alicyclic olefin resin-based transparent resin film) is coated. Then, the resin film 69 is formed by carrying out exposure using a signal line, source electrode wire, and drain electrode wire photomask, development, and heat hardening. Thus, wiring grooves 68 that serve as signal line, source electrode wire, and drain electrode wire regions were obtained (see FIG. 9, (h), although illustration is omitted in FIG. 9, (h), the wiring grooves 68 are defined between the resin film 69 and resin films separately formed like the resin film 69).

When the wiring width is very small, treatment may be carried out to provide water repellency to the surface of the resin film 69 for the purpose of enhancing the printing accuracy. Specifically, drying is carried out after oxygen plasma treatment and then the glass substrate is exposed in a fluorine gas atmosphere to fluorinate the surface thereof and, after annealing, immersed in a hydrofluoric acid aqueous solution. Then, a wiring precursor is filled in the foregoing groove portions by the printing method such as the inkjet printing method or the plating method. The inkjet method is preferable as the wiring forming method in terms of efficient use of ink, but use may also be made of a screen printing method or the like.

In this Example, silver paste ink as disclosed in Japanese Unexamined Patent Application Publication (JP-A) No. 2002-324966 was used as the wiring precursor to thereby form the wiring. After filling the wiring precursor, burning was carried out at a temperature of 250 degrees for 30 minutes. Thus, wires 71 were formed (see FIG. 10, (i)).

In this manner, the formation of a TFT was completed.

Then, an alicyclic olefin resin-based thermosetting photosensitive transparent resin was formed and subjected to exposure and development. Thus, an interlayer insulating film (corresponding to 47 in FIG. 6) formed with a contact hole from the pixel electrode 56 to the TFT electrode was obtained. In order to increase the light transmittance of the interlayer insulating film 47, the thermosetting photosensitive transparent resin was subjected to hardening by burning at 250° C. for 60 minutes by the use of a SUS316 heating apparatus electrolytically polished on its inner surface, while controlling the residual oxygen concentration at 10 vol ppm. Subsequently, an ITO was sputter-deposited on the entire substrate surface and then patterned so as to be the pixel electrode 56. A transparent conductive film material such as SnO₂ may be used instead of the ITO. By forming a polyimide film on the surface thereof as the orientation film 45 of the liquid crystals 44 and holding the liquid crystals 44 between the orientation film 45 and the opposing substrate 41, an active matrix liquid crystal display device was obtained.

According to the active matrix liquid crystal display device of this Example, since the fine wiring was accurately formed and the transparency of the interlayer insulating film 47 was high, it was possible to obtain a high-quality display with low power consumption and high brightness.

### INDUSTRIAL APPLICABILITY

According to a circuit board manufacturing method of this invention, it is possible to easily obtain a circuit board in which sufficient contrast is given to wettability of a liquid conductive material between a partition member and an insulating substrate without degrading the partition member so that fine wiring formation can be realized by an inkjet method or the like. Such a circuit board can be suitably used as a display device such as a liquid crystal display device, an organic EL display device, or a plasma address display device.

1. A method for manufacturing a circuit board, comprising the steps of:
forming a resin film on an insulating substrate, thereafter
exposing and developing said resin film,
heat-hardening said resin film, and
exposing said resin film to a fluorine gas atmosphere after drying said resin film.

2. A method for manufacturing a circuit board, comprising the steps of:
forming a resin film on an insulating substrate,
exposing and developing said resin film,
heat-hardening said resin film,
drying said resin film, and thereafter
exposing said resin film to a fluorine gas atmosphere.

3. A method for manufacturing a circuit board, comprising the steps of:
forming a resin film on an insulating substrate,
exposing and developing said resin film,
drying said resin film,
exposing said resin film to a fluorine gas atmosphere, and thereafter
heat-hardening said resin film.

4. A method for manufacturing a circuit board, comprising the steps of:
forming a resin film on an insulating substrate,
heat-hardening said resin film,
drying said resin film,
exposing said resin film to a fluorine gas atmosphere, and
exposing and developing said resin film.

5. The method for manufacturing a circuit board according to claim 1, wherein:
the water content in said resin film is 1 wt % or less after the drying step.

6. The method for manufacturing a circuit board according to claim 1, wherein:
the water concentration in the fluorine gas atmosphere is 100 wt ppm or less.

7. The method for manufacturing a circuit board according to claim 1, wherein:
the step of heat-hardening said resin film is carried out in an inert gas atmosphere.

8. The method for manufacturing a circuit board according to claim 1, wherein:
said resin film is subjected to ultraviolet irradiation at atmospheric pressure before the step of exposing said resin film to the fluorine gas atmosphere.

9. The method for manufacturing a circuit board according to claim 1, further comprising the step of:
applying oxygen plasma treatment to said resin film at normal pressure or reduced pressure before the step of exposing said resin film to the fluorine gas atmosphere.

10. The method for manufacturing a circuit board according to claim 1, further comprising the step of:
contacting said insulating substrate with a hydrofluoric acid-based chemical solution after the step of exposing said resin film to the fluorine gas atmosphere.

11. The method for manufacturing a circuit board according to claim 10, wherein:
the hydrofluoric acid-based chemical solution is a hydrofluoric acid aqueous solution having a hydrofluoric acid concentration of 0.1 wt % to 50 wt %.

12. The method for manufacturing a circuit board according to claim 10, wherein:
the hydrofluoric acid-based chemical solution contains one or more kinds of chemicals selected from the group consisting of inorganic acids, fluoride salts, and surfactants.

13. The method for manufacturing a circuit board according to claim 1, further comprising the step of:
filling a conductive material in a concave portion formed by development of said resin film to form electrical wiring.

14. The method for manufacturing a circuit board according to claim 13, wherein:
filling of the conductive material is carried out by any one of a plating method and a printing method.

15. The method for manufacturing a circuit board according to claim 14, wherein:
the printing method is inkjet printing or screen printing.

16. The method for manufacturing a circuit board according to claim 1, wherein:
said resin film and said electrical wiring form substantially the same plane.

17. The method for manufacturing a circuit board according to claim 1, wherein:
said insulating substrate is a glass substrate or a silicon wafer.

18. The method for manufacturing a circuit board according to claim 13, wherein:
the conductive material comprises an organic substance.

19. The method for manufacturing a circuit board according to claim 1, wherein:
said resin film is made from a photosensitive resin composition comprising an alkali-soluble alicydic olefin resin and a radiation-sensitive component.

20. The method for manufacturing a circuit board according to claim 1, wherein:
said resin film comprises one or more kinds of resins selected from the group consisting of an acrylic resin, a silicone resin, a fluorine resin, a polyimide resin, a polyolefin resin, an alicyclic olefin resin, and an epoxy resin.

21. A circuit board obtainable by the method as defined in claim 1.

22. A display device comprising the circuit board as defined in claim 21.

23. The display device according to claim 22, wherein:
said display device is a liquid crystal display device, an organic EL display device, or a plasma address display device.
